(19) United States
(12) Patent Application Publication
(10) Pub. No.: US 2008/0017409 A1
(43) Pub. Date: Jan. 24, 2008

(54) Multilayer board

(75) Inventors: Satoshi Takeuchi, Nagoya-city (JP); Hiroki Kamiya, Nagoya-city (JP); Motoki Shimizu, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/806,485

(22) Filed: May 31, 2007

(30) Foreign Application Priority Data
Jun. 5, 2006 (JP) 2006-156687

(51) Int. Cl. H05K 1/16

(52) U.S. Cl. 174/260; 174/250

(57) ABSTRACT

A multilayer board includes a base member made of an insulation material. A plurality of conductor patterns is disposed in the base member in a multi-layered manner. A plurality of interlayer connectors is disposed in the base member, and is electrically connected to the conductor pattern by a heating process. An electronic device is disposed in the base member, and is electrically connected to at least one of the interlayer connector and the conductor pattern. The electronic device includes an electrode made of a material having a melting point higher than a temperature of the heating process.

### CROSS REFERENCE TO RELATED APPLICATION

This application is based on Japanese Patent Application No. 2006-156687 filed on Jun. 5, 2006, the disclosure of which is incorporated herein by reference in its entirety.

### BACKGROUND OF THE INVENTION

1. Field of the Invention

The present invention relates to a multilayer board having an electronic device therein.

2. Description of Related Art

A multilayer board having an electronic device therein is constructed by a plurality of single-sided conductor pattern films (resin films). At least one of a conductor pattern and an interlayer connector is formed in the film. Further, a through hole is provided in some of the films, and the multiple films having the through hole are layered. When the through hole is covered with a film not having the through hole, a recession can be formed in the layered films. An electronic device having an electrode is arranged in the recession, and the recession is covered with another film not having the through hole. Then, the layered films are heated and pressed from the both sides to produce the multilayer board.

A size of the recession may be made slightly larger than an outer shape of the electronic device in consideration of variations of the outer shape of the electronic device, accuracy for processing the through hole, and accuracy for positioning the electronic device. Therefore, a clearance may be generated between the electronic device and the recession.

In contrast, the electrode of the electronic device may be melted due to a superheat at the heating and pressing process, if a material constructing the electrode has a melting point lower than a temperature of the heating and pressing process.

Thus, when the electronic device disposed in the recession is heated, the electrode may be melted and flow into the clearance. In this case, connection reliability may be lowered when plural electronic devices are disposed in the multilayer board, because plural electrodes may be connected to each other by the melting.

### SUMMARY OF THE INVENTION

In view of the foregoing and other problems, it is an object of the present invention to provide a multilayer board.

According to a first example of the present invention, a multilayer board includes a base member made of an insulation material. A plurality of conductor patterns is disposed in the base member in a multi-layered manner. A plurality of interlayer connectors is disposed in the base member, and the interlayer connector is electrically connected to the conductor pattern by a heating process. An electronic device is disposed in the base member, and is electrically connected to at least one of the interlayer connector and the conductor pattern. The electronic device includes an electrode made of a material having a melting point higher than a temperature of the heating process.

According to a second example of the present invention, a multilayer board includes an insulating base member, a multilayer conductor and an electronic device. The insulating base member is made of resin films heated in a heating process. The multilayer conductor is located in the insulating base member. The electronic device includes an electrode electrically connected to the multilayer conductor. The electrode has a melting point higher than a temperature of the heating process.

Accordingly, connection reliability of the electrode of the electronic device can be improved.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic cross-sectional view showing a multilayer board according to an embodiment of the present invention;

FIGS. 2A to 2F are step-by-step cross-sectional views showing the summarized production process of the multilayer board;

FIG. 3A is a perspective view showing an electronic device to be mounted in the multilayer board, and FIG. 3B is a perspective view showing the electronic device mounted in the multilayer board;

FIG. 4A is an enlarged cross-sectional view showing the electronic device to be mounted in the multilayer board, and FIG. 4B is an enlarged cross-sectional view showing the electronic device mounted in the multilayer board; and

FIG. 5A is a cross-sectional view taken along line V-V in FIG. 4B, in which an electrode of the electronic device is made of tin, and FIG. 5B is a cross-sectional view taken along line V-V in FIG. 4B, in which the electrode of the electronic device is made of gold.

### DETAILED DESCRIPTION OF PREFERRED EMBODIMENT

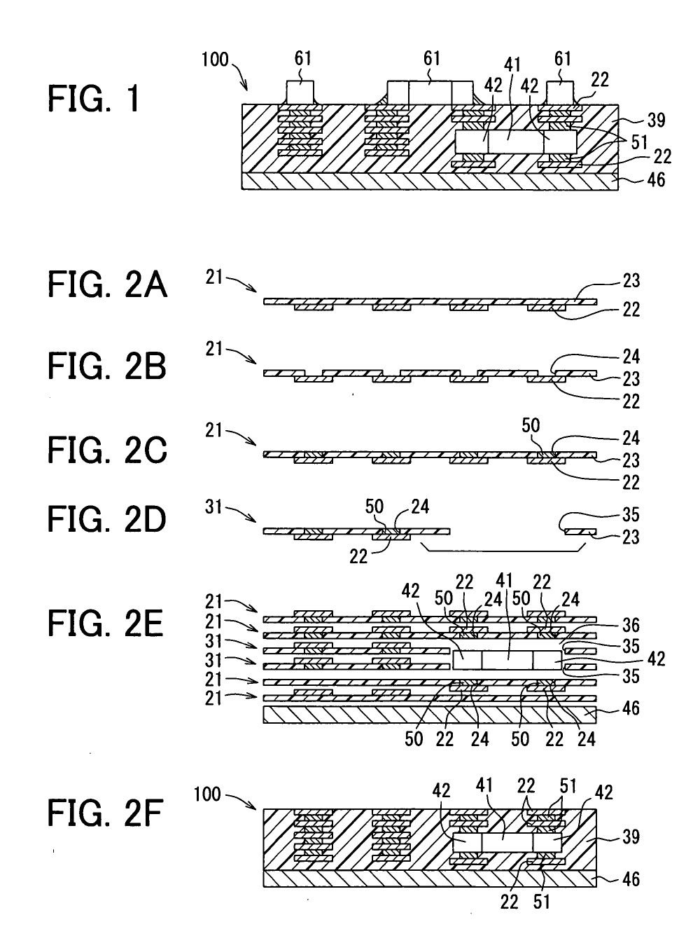

As shown in FIG. 1, a multilayer board 100 includes a conductor pattern 22, an insulation member 39 (base member), conductive compounds 51 (an interlayer connector) and an electronic device 41. The insulation member 39 is made of resin films 23 shown in FIGS. 2C and 2D, and the resin films 23 are securely bonded to each other in the insulation member 39. The electronic device 41 is positioned in the insulation member 39, and electrically connected to the conductor pattern 22. The electronic device 41 is sealed in the insulation member 39.

The multilayer board 100 includes a heat sink 46 on at least one side, e.g., lower face, of the multilayer board 100. Therefore, heat can be easily radiated from the multilayer board 100, even when another electronic device 61 is mounted on a top face of the multilayer board 100, in addition to the electronic device 41 disposed in the multilayer board 100. The insulation member 39 has heat conductivity lower than that of metal, so that heat cannot easily be radiated from the insulation member 39. However, due to the heat sink 46 made of metal having better heat conductivity, the heat conductivity of the multilayer board 100 can be efficiently raised, so that heat can be easily radiated from the multilayer board 100.

The electronic device 41 is constructed by a resistor, capacitor, filter or IC, for example. The electronic device 41 has an electrode 42 at each end to be electrically connected to the conductor pattern 22 and a conductive paste 50 shown in FIG. 2C. The conductive paste 50 becomes the conductive compounds 51 after heated. The electrode 42 is formed on a face of the electronic device 41 in a layer direction of the films 23.

In order to form the electrode 42, a primary (foundation) electrode is formed on a surface adjacent to the end of the electronic device 41. For example, Cu, NiCr or Ni is coated on a predetermined area from the end of the electronic device 41 by sputtering, ion plating or vapor deposition. Then, a material having a melting point higher than a temperature of a heating process to be performed thereafter is arranged on a surface of the primary electrode by electrolytic plating, as the electrode 42. The material is made of gold, nickel, copper, alloy of copper and nickel, silver or conductive paste, for example. The electrode 42 is made of a material not to be oxidized in air, such as gold.

The conductive paste constructing the electrode 42 is made of a first metal and a second metal. The first metal is capable of forming an alloy with at least one of the conductive compounds 51 and the conductor pattern 22. The second metal has a melting point higher than the temperature of the heating process. Specifically, the conductive paste is disclosed in JP-A-2003-110243, which is hereby incorporated by reference. Organic solvent (e.g., terpineol) of 60 g is added into tin particles of 300 g and silver particles of 300 g, and mixed into a paste by a mixer. The tin particle has an average diameter of about 5 μm and a specific surface area of about 0.5 m²/g, and the silver particle has an average diameter of about 1 μm and a specific surface area of about 1.2 m²/g.

Here, a method of producing the multilayer board 100 will be described. As shown in FIG. 2A, a single-sided conductor pattern film 21 includes the resin film 23 and the conductor pattern 22 on a single face of the resin film 23. The resin film 23 is made of an insulation material, and the conductor pattern 22 is formed by etching a conductor foil (e.g., copper foil having a thickness of 18 μm) bonded to the single face of the resin film 23. The resin film 23 is a thermoplastic resin film having a thickness of 75 μm, and is made of a mixture of polyether ether ketone resin of 65-35% by weight and polyether imide resin of 35-65% by weight, for example.

After the conductor pattern 22 is formed, carbon dioxide gas laser is irradiated toward the resin film 23 to form a via hole 24, as shown in FIG. 2B. The via hole 24 has a bottom face constructed by the conductor pattern 22. Output power and irradiation time of the carbon dioxide gas laser are controlled to prevent from making a hole in the conductor pattern 22.

Excimer laser may be used for forming the via hole 24. Other than the lasers, drilling may be used for forming the via hole 24. However, when laser beam is used for forming the via hole 24, the via hole 24 can have a better accuracy, and damage to the conductor pattern 22 can be reduced.

After the via hole 24 is formed, the conductive paste 50 is filled in the via hole 24 as an electrical connection material, as shown in FIG. 2C. In order to form the conductive paste 50, organic solvent (e.g., terpineol) of 60 g, in which ethyl cellulose resin of 6 g is dissolved, is added into tin particles of 300 g and silver particles of 300 g, and mixed into a paste by a mixer. The tin particle has an average diameter of about 5 μm and a specific surface area of about 0.5 m²/g, and the silver particle has an average diameter of about 1 μm and a specific surface area of about 1.2 m²/g.

Here, the ethyl cellulose resin is added to provide a shape retaining property to the conductive paste 50. Alternatively, acrylic resin may be used in place of the ethyl cellulose resin.

The conductive paste 50 is printed to be filled in the via hole 24 of the single-sided conductor pattern film 21 by a screen printer using metal mask, and the terpineol in the conductive paste 50 is dried at about 140-160° C. for about 30 minutes. Alternatively, the conductive paste 50 may be filled in the via hole 24 using a dispenser.

Here, organic solvent having a boiling point in a range between 150° C. and 300° C. may be used in place of the terpineol. However, if the organic solvent has the boiling point lower than 150° C., viscosity of the conductive paste 50 may have a large variation as time elapses. In contrast, if the organic solvent has the boiling point higher than 300° C., time necessary for the drying may be increased.

The tin particle has the average diameter of about 5 μm and the specific surface area of about 0.5 m²/g, and the silver particle has the average diameter of about 1 μm and the specific surface area of about 1.2 m²/g. Alternatively, the tin particle or the silver particle may have the average diameter of about 0.5-20 μm and the specific surface area of about 0.1-1.5 m²/g.

If the particle has the average diameter smaller than 0.5 μm, or if the particle has the specific surface area larger than 1.5 m²/g, a large amount of the organic solvent is needed to make the conductive paste 50 to have the viscosity suitable for filling the via hole 24. If the conductive paste 50 contains the large amount of the organic solvent, time for the drying is increased. If the drying is insufficient, a large amount of gas is generated when the conductive paste 50 is heated for interlayer connection. Thus, void may be easily generated in the via hole 24, so that reliability of the interlayer connection may be lowered in this case.

In contrast, if the particle has the average diameter larger than 20 μm, or if the particle has the specific surface area smaller than 0.1 m²/g, the conductive paste 50 is difficult to be filled in the via hole 24. Further, the particles may be unevenly distributed, so that homogeneous alloy (i.e., conductive compounds 51) cannot be formed when the conductive paste 50 is heated. In this case, the reliability of the interlayer connection may be difficult to be secured.

Further, before the conductive paste 50 is filled in the via hole 24, etching treatment or reduction treatment may be slightly performed relative to a part of the conductor pattern 22 facing the via hole 24. Thus, via connection (interlayer connection) to be described below can be accurately performed.

As shown in FIG. 2D, a single-sided conductor pattern film 31 includes the resin film 23 and the conductor pattern 22 on a single face of the resin film 23, similar to the single-sided conductor pattern film 21 shown in FIG. 2A. The via hole 24 is formed in the film 31, and the conductive paste 50 is filled in the via hole 24 of the film 31, similar to the single-sided conductor pattern film 21 shown in FIGS. 2B and 2C.

When the via hole 24 is formed in the single-sided conductor pattern film 31, a through hole 35 is also formed in the single-sided conductor pattern film 31, at the same time. The through hole 35 is located at a position corresponding to a position of the electronic device 41, and the through hole 35 has a shape corresponding to an outer shape of the electronic device 41 due to the laser processing.

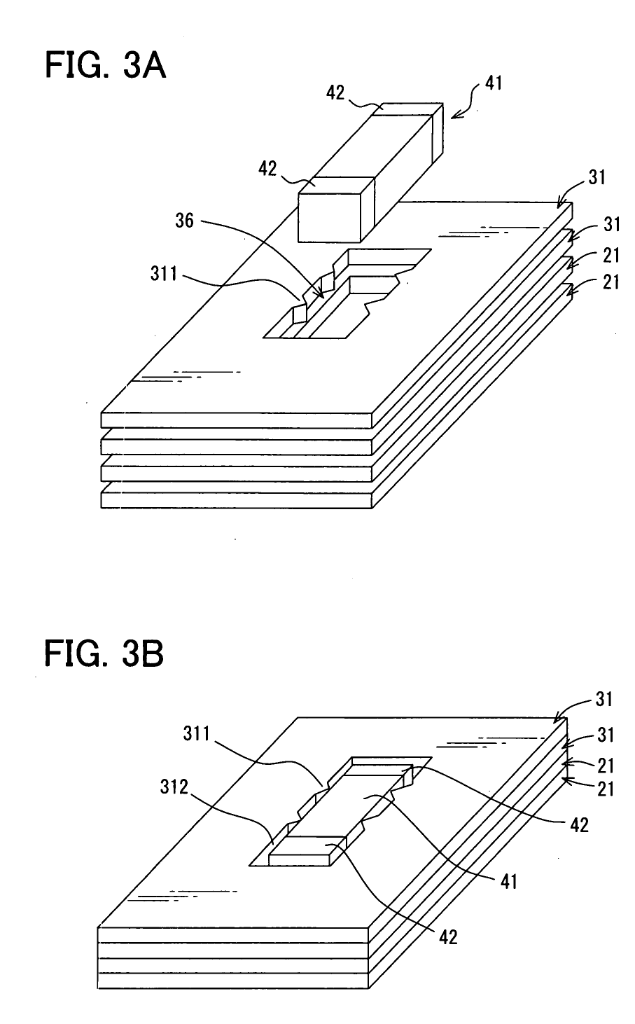

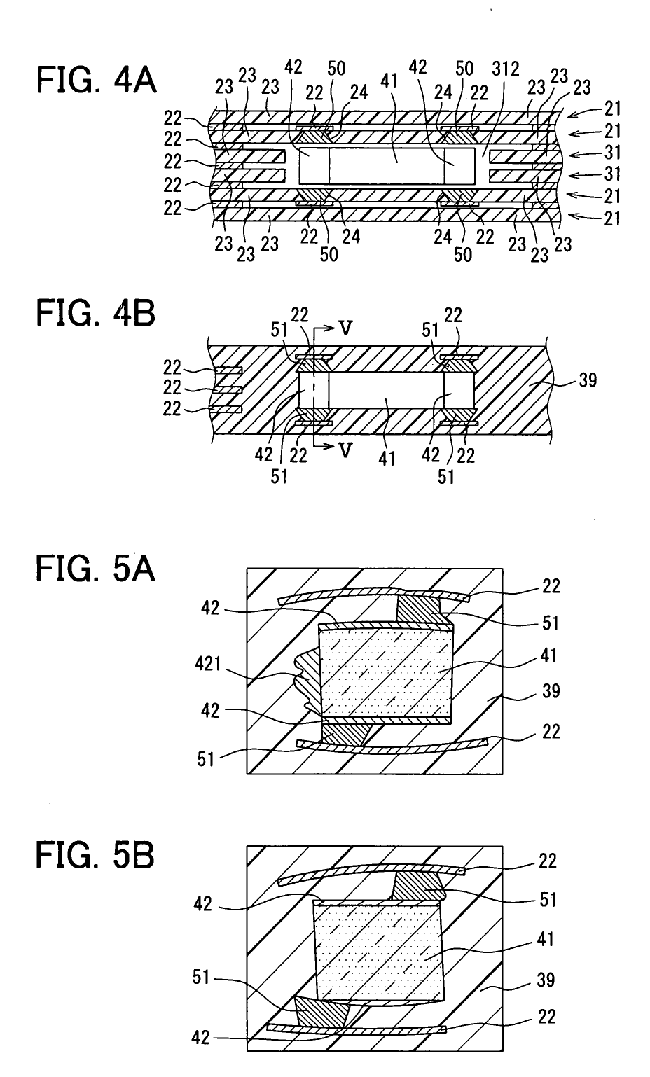

As shown in FIG. 3A, the single-sided conductor pattern film 31 partly has a protrusion 311 for positioning and fixing the electronic device 41 at an appropriate position when the electronic device 41 is inserted into a space 36 constructed by the through hole 35. Adhesive may be used in place of the protrusion 311 for the positioning and the fixing. As shown in FIG. 3B, when the electronic device 41 is inserted into the space 36, a clearance 312 between the electronic device 41 and the film 31 has a dimension equal to or larger than 20 μm. Further, the dimension of the clearance 312 is equal to or smaller than a thickness (e.g., 75 μm) of the resin film 23. The clearance 312 is provided over all periphery of the electronic device 41. Further, as shown in FIG. 4A, a clearance by a thickness of the conductor pattern 22 is provided between the single-sided conductor pattern films 21, 31, when the single-sided conductor pattern films 21, 31 are layered.

The through hole 35 is formed by the laser processing at the same time as the via hole 24 is formed. Alternatively, the through hole 35 may be formed by a punching process or router process at a timing other than the timing for forming the via hole 24.

Here, the resin film 23 of the single-sided conductor pattern film 31 is made of the thermoplastic resin film having the thickness of 75 μm, and is made of the mixture of polyether ether ketone resin of 65-35% by weight and polyether imide resin of 35-65% by weight, similar to the resin film 23 of the single-sided conductor pattern film 21.

After the through hole 35 is formed in the single-sided conductor pattern film 31 and the conductive paste 50 is filled in the via hole 24 of the single-sided conductor pattern film 21, 31 and dried, a plurality (e.g., six) of the single-sided conductor pattern films 21, 31 are layered, as shown in FIG. 2E.

At this time, the single-sided conductor pattern films 21, 31 are layered such that the conductor pattern 22 is disposed on the top face of the single-sided conductor pattern film 21, 31. That is, the single-sided conductor pattern films 21, 31 are layered such that the top face of the resin film 23, on which the conductor pattern 22 is formed, opposes to a back face of the upper resin film 23, on which the conductor pattern 22 is not formed.

Here, as shown in FIG. 2E, adjacent films 31 having the through hole 35 at the same position are layered such that a depth of the space 36 corresponds to a thickness of the electronic device 41. Because the electronic device 41 has the thickness of 160 μm in this embodiment, two of the adjacent films 31 having the thickness of 75 μm are layered. Thus, the space 36 has the depth of 150 μm, which is equal to or smaller than the thickness of the electronic device 41. When the single-sided conductor pattern films 21, 31 are layered, the electronic device 41 is inserted into the space 36 constructed by the through holes 35. The depth of the space 36 can be easily controlled by adjusting the number of the resin films 23.

Then, the single-sided conductor pattern film 21 is layered at a top side of the space 36. This single-sided conductor pattern film 21 has the via hole 24 filled with the conductive paste 50 to be electrically connected to the conductor pattern 22 and the electrode 42.

Further, the heat sink 46 made of aluminum is disposed on a back face of the layered films 21, 31. The heat sink 46 is a metal base member in this embodiment. The lowest resin film 23 to be in contact with the heat sink 46 does not have the via hole 24. The multilayer board 100 includes the insulation member 39, whose heat conductivity is lower than that of metal. However, when the heat sink 46 is disposed on at least a single face of the layered films 21, 31, heat conductivity of the multilayer board 100 can be efficiently improved, so that heat can be easily radiated from the multilayer board 100.

After layered as shown in FIG. 2E, the films 21, 31 and the heat sink 46 are heated and pressed by a vacuum heating and pressing machine from the both sides (top and bottom). For example, the heating is performed at about 250-350° C., and the pressing is performed at a pressure of about 1-10 Mpa for about 10-20 minutes.

Thereby, as shown in FIG. 2F, the films 21, 31 and the heat sink 46 can be connected to each other. Because the resin films 23 are made of the same thermoplastic resin material, the resin films 23 can be easily melted to integrate into the insulation member 39. Thus, the electronic device 41 can be completely sealed in the insulation member 39 without any clearance.

Further, the conductive paste 50 in the via hole 24 is sintered and integrated into the conductive compounds 51. The conductive compounds 51 connect the adjacent conductor patterns 22 as the interlayer connector. Furthermore, the electrode 42 of the electronic device 41 and the conductor pattern 22 can be connected to each other. Thus, the multilayer board 100 having the electronic device 41 therein can be produced.

Here, mechanism of the interlayer connection between the conductor patterns 22 will be briefly described. When the conductive paste 50 filled in the via hole 24 is dried, the tin particles and the silver particles are mixed in the conductive paste 50. When the conductive paste 50 is heated at about 250-350° C., the tin particles are melted and adhered to cover outer periphery of the silver particles, because the tin particle has the melting point of 232° C. and the silver particle has the melting point of 961° C.

When the heating is continued in this state, the melted tin starts to diffuse into the surface of the silver particle to form an alloy of the tin and the silver. The alloy has the melting point of 480° C. At this time, because the pressure of 1-10 MPa is applied to the conductive paste 50, the conductive compounds 51 made of the alloy can be formed in the via hole 24.

When the conductive compounds 51 are formed in the via hole 24, the conductive compounds 51 are pressed to a face of the conductor pattern 22 constructing a bottom part of the via hole 24. Thereby, the tin component in the conductive compounds 51 and the copper component in the copper foil constructing the conductor pattern 22 diffuse into each other in a solid phase. Thus, solid-phase diffusion layer can be formed at an interface between the conductive compounds 51 and the conductor pattern 22 to be electrically connected.

Further, as shown in FIG. 4B, the electrode 42 of the electronic device 41 is electrically connected to the conductor pattern 22 through a metal diffusion layer, due to an approximately the same mechanism of the solid-phase diffusion layer between the conductive compounds 51 and the conductor pattern 22 described above. The metal diffusion layer is formed at an interface between the conductive compounds 51 and the conductor pattern 22, and an interface between the conductive compounds 51 and the electrode 42. Due to the metal diffusion layer, the electrode 42 can be more solidly connected to the conductor pattern 22 through the conductive compounds 51.

A coefficient of elasticity of the resin film 23 is lowered to about 5-40 MPa when the resin film 23 is heated and pressed by the vacuum heating and pressing machine. Therefore, the resin film 23 adjacent to the through hole 35 is deformed to protrude in the through hole 35. Further, the resin film 23 opposing to the through hole 35 in the film layer direction is also deformed to protrude in the through hole 35. That is, the resin film 23 adjacent to the space 36 is pushed toward the space 36.

Thereby, the electronic device 41 can be sealed by the insulation member 39 integrated with the deformed resin films 23. The resin film 23 may have the coefficient of elasticity in a range of 1-1000 MPa, when the resin films 23 are heated and pressed. If the resin film 23 has the coefficient of elasticity larger than 1000 MPa, the resin films 23 may be difficult to be connected to each other, and the resin film 23 may be difficult to be deformed. If the resin film 23 has the coefficient of elasticity smaller than 1 MPa, the resin film 23 is easily fluidized by the pressing, so that the multilayer board 100 may be difficult to be produced.

Further, in a case where the electrode 42 of the electronic device 41 is made of a material such as tin having the melting point lower than the temperature of the heating process, the electrode 42 is melted when heated and pressed by the vacuum heating and pressing machine. The melted electrode 42 may form a pour area 421 in a comparison example shown in FIG. 5A, because the melted electrode 42 is pushed and flow into the clearance 312 (see FIG. 3B) when the resin film 23 is pushed toward the space 36 (see FIG. 3A).

When the melted electrode 42 of the electronic device 41 flows into the clearance 312 to form the pour area 421, the pour area 421 may be electrically connected to the conductor pattern 22 or not intended portion (e.g., other electrode) of the electronic device 41. In this case, connection reliability may be lowered.

However, in this embodiment, a material having the melting point higher than the temperature of the heating process is used as the electrode 42 of the electronic device 41. For example, the material is made of gold, nickel, copper, alloy of copper and nickel, silver or conductive paste. Thus, as shown in FIG. 5B, the electrode 42 is not melted, and does not flow into the clearance 312 when pressed and heated by the machine. Therefore, connection reliability of the electrode 42 of the electronic device 41 can be kept better, so that the electrode 42 can be solidly connected to at least one of the conductive compounds 51 and the conductor pattern 22.

The electrode 42 of the electronic device 41 is formed on the face of the electronic device 41 in the film layer direction, in order to be electrically connected to the conductor pattern 22. Alternatively, the electrode 42 may be formed on the electronic device 41 in a direction except for the film layer direction. That is, the electrode 42 is arranged on a first face of the electronic device 41 in the film layer direction, and a second face approximately perpendicular to the first face of the electronic device 41.

When the multilayer board 100 includes an electrical wiring in a clearance between the electrode 42 and the resin film 23, the electrical wiring is insulated from the electrode 42. Therefore, short circuit or malfunction can be reduced between the electrode 42 and the electrical wiring. When at least two resin films 23 are layered adjacent to the electrode 42, the clearance may be one of a plurality of clearances provided between the electrode 42 and the resin film 23.

The resin film 23 is made of the mixture of polyether ether ketone resin of 65-35% by weight and polyether imide resin of 35-65% by weight. Alternatively, a film, in which any non-conductive filler is filled in the polyether ether ketone resin and the polyether imide resin, may be used as the resin film 23. The polyether ether ketone (PEEK) or the polyether imide (PEI) may be solely used as the resin film 23.

Further, a thermoplastic resin, e.g., polyphenylene sulfide (PPS), thermoplastic polyimide or liquid crystal polymer, may be used as the resin film 23. Any resin film having the coefficient of elasticity of about 1-1000 MPa in the heating process, or any resin film having a heat resistance necessary for a soldering process to be performed thereafter may be used as the resin film 23.

The heat sink 46 is arranged on the whole lowest face of the multilayer board 100. Alternatively, the heat sink 46 may be arranged on the lowest face of the multilayer board 100 in part, or on the both faces (the lowest face and the top face). Further, when the heat radiation property is not required to be raised, the heat sink 46 may not be arranged on the multilayer board 100.

In order to arrange the heat sink 46 on the multilayer board 100, a bonding sheet may be disposed on an adhesion face of the heat sink 46 to be connected to the insulation member 39. For example, polyether imide sheet, thermosetting resin sheet including heat conductive fillers or thermoplastic resin sheet including heat conductive fillers may be used as the bonding sheet, in order to improve the adhesion property and the heat conductivity.

Further, the multilayer board 100 is made of six layers in the above description. However, the number of the layers is not limited to six.

Such changes and modifications are to be understood as being within the scope of the present invention as defined by the appended claims.

What is claimed is:

1. A multilayer board comprising:
a base member made of an insulation material;
a plurality of conductor patterns disposed in the base member in a multi-layered manner;
a plurality of interlayer connectors disposed in the base member, wherein the interlayer connector is electrically connected to the conductor pattern by a heating process; and
an electronic device disposed in the base member, wherein
the electronic device is electrically connected to at least one of the interlayer connector and the conductor pattern, and
the electronic device includes an electrode made of a material having a melting point higher than a temperature of the heating process.

2. The multilayer board according to claim 1, wherein
the base member is made of a plurality of resin films including at least one of the interlayer connector and the conductor pattern,
the electronic device is disposed in a space constructed by a through hole provided in the resin film.

3. The multilayer board according to claim 2, wherein
the resin film includes a thermoplastic resin film.

4. The multilayer board according to claim 1, wherein
the electrode is made of at least one of gold, nickel, copper, alloy of copper and nickel, silver and conductive paste, and
the conductive paste is made of a fist metal capable of forming an alloy with at least one of the interlayer connector and the conductor pattern, and a second metal having the melting point higher than the temperature of the heating process.

5. The multilayer board according to claim 1, wherein
the electrode is electrically connected to at least one of the interlayer connector and the conductor pattern through a metal diffusion layer, and
the metal diffusion layer is provided at an interface between the electrode and at least one of the interlayer connector and the conductor pattern.

6. The multilayer board according to claim 1, wherein
the electrode is arranged on a first face of the electronic device in a layer direction, and a second face approximately perpendicular to the first face of the electronic device.

7. The multilayer board according to claim 2, further comprising:
an electrical wiring disposed in a clearance between the electrode and the resin film, wherein
the electrical wiring is insulated from the electrode.

8. The multilayer board according to claim 7, wherein
at least two resin films are layered adjacent to the electrode, and
the clearance is one of a plurality of clearances provided between the electrode and the resin film.

9. A multilayer board comprising:
an insulating base member made of resin films heated in a heating process;
a multilayer conductor located in the insulating base member; and
an electronic device including an electrode electrically connected to the multilayer conductor, wherein
the electrode has a melting point higher than a temperature of the heating process.

10. The multilayer board according to claim 9, wherein the electrode is disabled to be melted in the heating process.
